(19) United States
(12) Patent Application Publication
(10) Pub. No.: US 2020/0273629 A1
(43) Pub. Date: Aug. 27, 2020

(54) LIGAND MODIFIED PEROVSKITE OPTOELECTRONIC DEVICES

(71) Applicant: THE UNIVERSITY OF HONG KONG, Hong Kong (CN)

(72) Inventors: Chik Ho Wallace CHOY, Hong Kong (CN); Hong ZHANG, Hong Kong (CN)

(21) Appl. No.: 16/759,606

(22) PCT Filed: Oct. 17, 2018
(86) PCT No.: PCT/CN2018/110581

§ 371 Date: Apr. 27, 2020

Related U.S. Application Data
(60) Provisional application No. 62/577,419, filed on Oct. 26, 2017.

(51) Int. Cl. H01G 9/20; H01L 51/00; C07F 7/24; H01G 9/00; H01L 51/42; H01L 51/44

(52) U.S. Cl. CPC H01G 9/2009; H01L 51/0077; C07F 7/24; H01L 51/441; H01G 9/2018; H01L 51/0003; H01L 51/4253; H01G 9/0036

(57) ABSTRACT

A method of ligand-induced regional modification of a perovskite film of perovskite optoelectronic device can include generating a ligand atmosphere, exposing a perovskite optoelectronic device in the ligand atmosphere, and removing the perovskite optoelectronic device from the ligand atmosphere. Methods for improving the performance and stability of perovskite optoelectronic devices are performed by using a ligand-induced modification of complete devices at room temperature. This post-device treatment, completely separated from the fabrication process of common perovskite optoelectronic devices, provides a general strategy to improve the stability of different completed perovskite optoelectronic devices (i.e., perovskite solar cells, perovskite light-emitting diodes, and photodetectors) without introducing any undesirable impurities during device fabrication.

### BACKGROUND OF THE INVENTION

Perovskite optoelectronic devices (e.g., perovskite solar cells, perovskite light-emitting diodes, and perovskite photodetectors) have drawn enormous attention with remarkably high performance and prospective for low-cost fabrication. A new certificated efficiency of 22.1% has recently been achieved in perovskite solar cells, which enables them as a very promising candidate to be used for next-generation photovoltaics. However, perovskite optoelectronic devices still suffer from poor stability caused by moisture, oxygen, light illumination, applied electric field, thermal stress, and iodine vapor. Among them, moisture has been demonstrated as the most prominent factors for perovskite degradation due to the strong interaction with water molecule. Some strategies have been reported to solve this issue, e.g. forming water-resisting layer, adding water-proofing additives, and using two-dimensional (2D)/three-dimensional (3D) perovskite mixtures. While the stability is improved, these approaches incorporate insulating moieties in the perovskite lattice or film surfaces, which may affect the charge separation and transport processes in perovskites or charge extraction from perovskite to carrier transport layers. Besides, these methods are introduced during the core-device fabrication and thus increase the risk of introducing unexpected impurities during the fabrication. It is thus desirable to improve the stability of perovskite optoelectronic devices by post-device treatment.

### BRIEF SUMMARY OF THE INVENTION

Embodiments of the subject invention are drawn to methods of improving the performance and stability of perovskite optoelectronic devices (i.e., perovskite solar cells, perovskite light-emitting diode, perovskite photodetectors) by using a new scheme of ligand-induced regional modification of perovskites at room temperature.

In an embodiment, a method of ligand-induced regional modification of a perovskite film of completed devices at room temperature can include: generating a ligand atmosphere; exposing the perovskite optoelectronic devices in the ligand atmosphere; and removing the perovskite optoelectronic devices from the ligand atmosphere. The ligand vapors modify the region of the perovskite film that is not protected by a contact film (e.g., a carrier transport layer, an electrode, a polymer film, and, inorganic film). The ligand modified perovskite film exhibits X-ray diffraction (XRD) peaks at an angle (2 theta) less than 12 degrees.

In another embodiment, a method of manufacturing a ligand treated perovskite optoelectronic device can comprise preparing the perovskite optoelectronic device, and performing a ligand treatment on a lateral region of the devices such that a perovskite film in the lateral region of the perovskite optoelectronic device has a ligand modified perovskite film.

In yet another embodiment, a ligand treated perovskite optoelectronic device can comprise a perovskite film, and the contact film disposed on the perovskite film and configured to cover a central region of the perovskite optoelectronic device and to expose a lateral region of the PVSC, wherein the perovskite film located in the lateral region of the perovskite optoelectronic device has a ligand modified perovskite film.

### BRIEF DESCRIPTION OF THE DRAWINGS

FIG. 1(a) is a schematic of ligand-induced modification of perovskite optoelectronic device according to embodiments of the subject invention.

FIG. 1(b) is the photograph of the perovskite optoelectronic device before and after ligand-induced modification.

FIG. 1(c) is a plot of X-ray powder diffraction (XRD) patterns of perovskite film before and after ligand modification.

FIG. 2(a) is a J-V curve and the relevant parameters (inserted) of a perovskite solar cell (PVSC) before and after ligand-induced modification.

FIG. 2(b) is the power conversion efficiency (PCE) distribution histogram of PVSCs before and after ligand-induced modification.

FIG. 3(a) is evolution of PCE relative to the initial parameters for the unencapsulated devices with and without ligand-induced modification over 15 days of storage in air. The humidity and temperature are 50±5% and 25±1° C., respectively.

FIG. 3(b) is a plot of maximum power point tracking for 500 h of the unencapsulated devices under continuous 1 sun illumination. The humidity and temperature are 50±5% and 25±1° C., respectively.

### DETAILED DISCLOSURE OF THE INVENTION

The subject invention relates to new multifunctional ligand-induced post-device treatment to significantly improve their performance, reproducibility, and stability simultaneously, which can help to form a platform to leverage the development in efficient and stable electronics with good reproducibility. Regarding the applications of, the post-device treatment is an independent process that can be integrated into any existent perovskite fabrication process after its completion, thus provides a general strategy to improve the critical stability issue, reduces the risk of introducing unexpected impurities during the fabrication, and reduces the cost and power consumption in fabrication, as well as be potentially size-scalable.

Perovskite optoelectronic devices (e.g., perovskite solar cells, perovskite light-emitting diodes, and perovskite photodetectors) have drawn enormous attention with remarkably high performance and prospective for low-cost fabrication. A new certificated efficiency of 22.1% has recently been achieved in perovskite solar cells, which enables them as a very promising candidate to be used for next-generation photovoltaics. However, perovskite optoelectronic devices still suffer from poor stability caused by moisture, oxygen, light illumination, applied electric field, thermal stress, and iodine vapor. Among them, moisture has been demonstrated as the most prominent factor for perovskite degradation due to the strong interaction with water molecule. Some strategies have been reported to solve this issue. For example, encapsulation [e.g., hydrophobic materials, epoxy resins, fluoropolymers] and interface engineering [e.g., using metal oxides to replace organic carrier transport layers] have been proposed to enhance the moisture stability of perovskite optoelectronic devices by blocking the away moisture, but the device still degrades at high humidity environment. Besides, the intrinsic moisture-sensitivity of perovskite films remains an unsolved problem. Recently, other strategies have been reported to solve this issue, e.g. forming water-resisting layer, adding water-proofing additives, and using two-dimensional (2D)/three-dimensional (3D) perovskite mixtures. While the stability is improved, these approaches incorporate insulating moieties in the perovskite lattice or film surfaces, which may affect the charge separation and transport processes in perovskites or charge extraction from perovskite to carrier transport layers. Besides, these methods are introduced during the core-device fabrication and thus increase the risk of introducing unexpected impurities during the fabrication. It is thus desirable to improve the stability of perovskite optoelectronic devices by post-device treatment.

Embodiments of the subject invention are drawn to methods of improving the performance and stability of the as-fabricated perovskite solar cells using a new scheme of ligand-induced regional modification of perovskite at room temperature.

Methods according to the subject invention provide a simple and low-cost approach for the improving the performance and stability of perovskite solar cells simultaneously at room temperature. In an embodiment, a method of ligand-induced regional modification of perovskite solar cells at room temperature can include: generating a ligand atmosphere; exposing the perovskite solar cells in the ligand atmosphere; and removing the perovskite solar cells form the ligand atmosphere. The ligand vapors modify the region of perovskite film that is not protected by a film. The ligand modified perovskite film exhibits X-ray diffraction (XRD) peaks at an angle (2 theta) less than 12 degree.

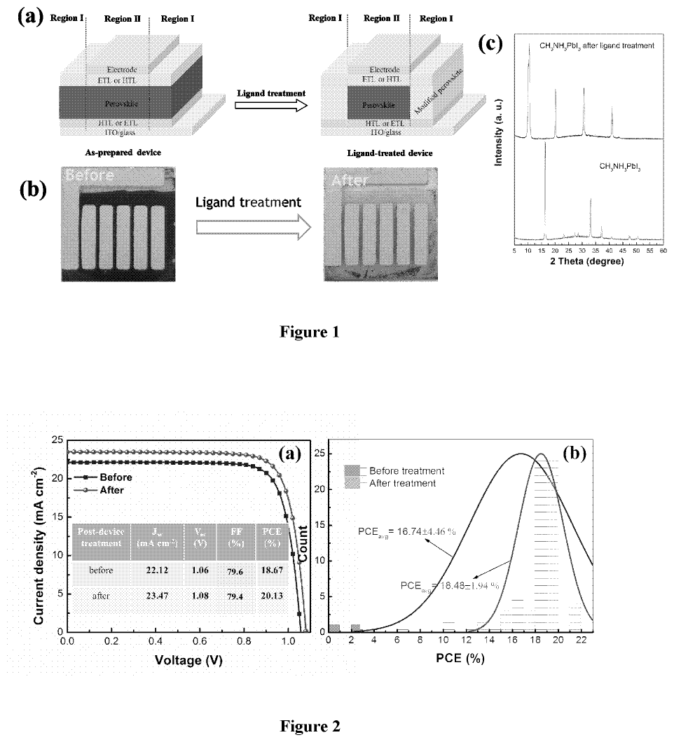

FIG. 1(a) shows a schematic of ligand-induced modification of perovskite optoelectronic devices according to embodiments of the subject invention, and FIG. 1(b) shows the photograph of perovskite optoelectronic devices before and after ligand-induced modification. Referring to the cross-sectional structural view for ligand-induced modification of perovskite optoelectronic devices as shown in FIG. 1(a), performed by the process of ligand-induced post-device treatment, the ligand sources modify the lateral regions (uncovered by a film) of perovskite optoelectronic devices perovskite film (i.e. region I in FIG. 1(a)) to form stable low-dimensional materials as shown in FIG. 1b, while the central region of the perovskite covered by a film (i.e. region II) is protected.

After manufacturing a perovskite optoelectronic device having the contact film that covers the central region of the perovskite optoelectronic device and exposes the lateral region of the perovskite optoelectronic device, the perovskite optoelectronic device is performed by a ligand treatment. During the ligand treatment, the perovskite film in the central region is not affected by the ligand treatment because it is covered by the contact film and the perovskite film in the lateral region is affected by the ligand treatment because the contact film does not block the ligand. Thus, the perovskite film in the lateral region changes to have a low-dimensional material characteristic that is different from the perovskite film in the central region.

FIG. 1(c) is a plot of X-ray powder diffraction (XRD) patterns of perovskite film before and after ligand modification. The properties of materials in region I and II (lateral region and central region) can be characterized by XRD as shown in FIG. 1(c). Referring to FIG. 1(c), a XRD peak in the lateral regions is located less than 12 degrees while a XRD peak in the central region is located higher than 12 degrees. That is, the ligand modified perovskite film in the lateral regions shows a low-dimensional material characteristic and the perovskite film in the central region shows a three-dimensional material characteristic.

The ligand used in this method can be ethylamine, propylamine, butylamine, amylamine, hexylamine, heptylamine, octylamine, ethylene diamine, diethylentriamine, or an alloy thereof.

The modification of perovskite optoelectronic devices by exposure to a ligand environment is processed by spin-coating with ligand solution, dipping in ligand solution, exposing in ligand vapor, or any combination thereof, though embodiments are not limited thereto. For example, the modification of perovskite optoelectronic devices can be processed by exposing in ligand vapor in three steps: i) generating ligand vapors in a closed container; ii) putting the devices in the formed ligand vapor atmosphere for several minutes; and iii) removing the treated devices out from the ligand vapor atmosphere.

The dosage of ligand can be, for example, any of the following values, about any of the following values, at least any of the following values, no more than any of the following values, or within any range having any of the following values as endpoints (all values are in microliter (μL)), though embodiments are not limited thereto: 1, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200. For example, the dosage of ligand solution can be between 1 μL and 150 μL.

The duration time between perovskite optoelectronic devices and ligand vapors can be, for example, any of the following values, about any of the following values, at least any of the following values, no more than any of the following values, or within any range having any of the following values as endpoints (all values are in minutes), though embodiments are not limited thereto: 1, 5, 10, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175 or 180.

The perovskite film (ABX₃) is an organic-inorganic hybrid or inorganic material, where A is CH₃NH₃⁺, HC(NH₂)₂⁺, Cs⁺, or an alloy thereof; B is Pb, Sn, Bi, or an alloy thereof; X is I, Cl, Br, SCN, or a mixture thereof, though embodiments are not limited thereto.

Methods of the subject invention can be carried out at room temperature and room pressure, i.e., at any suitable temperature and pressure present in a typical indoor setting. Advantageously, no toxic gases or chemicals are needed for the methods, and no toxic gases or chemicals are produced during the methods.

The subject invention includes, but is not limited to, the following exemplified embodiments.

### EMBODIMENT 1

A method of ligand-induced treatment on perovskite optoelectronic devices, the method comprising:
generating a ligand atmosphere;
exposing the perovskite optoelectronic devices in the ligand atmosphere; and
removing the perovskite optoelectronic devices from the ligand atmosphere.

### EMBODIMENT 2

The method according to embodiment 1, wherein a ligand for generating the ligand atmosphere is methylamine, dimethylamine, trimethylamine ethylamine, diethylamine, triethylamine, ethylenediamine, di ethy lentriamine, propylamine, 1,3-diaminopropane, dipropylamine, tri-n-propylamine, isopropylamine, diisopropylamine, 1,2-dimethylpropylamine, 1,2-diaminopropane, diallylamine, cyclopropylamine, butylamine, dibutylamine, isobutylamine, sec-butylamine, 1,4-diaminobutane, tert-butylamine, di is obutylamine, pentylamine, hexylamine, 2-ethy lhexy lamine, hexamethylenediamine, heptylamine, octylamine, tri-n-octylamine, 1,10-diaminodecane, N,N′-dimethylpropylenediamine, trimethylenediamine, N,N′-dihexyltrimethyl enediamine, decamethylenediamine, di(trimethylene)triamine, di(heptamethylene)triamine, triethylenetetraamine, tripropylenetraamine, tetraethylenepentaamine, pentaethylenehexaamine, imidazoline, methylimidazoline, bis(aminoethyl)imidazoline, pyrimidine, aminopropylpiperazine, bis(aminoethyl)piperazine, N-mono(hydroxyethyl)ethylenediamine, N,N′-bis(hydroxyethyl)ethylenediamine, N-mono(hydroxypropyl)diethylenetriamine and N,N′-bis(hydroxypropyl)tetraethylenepentaamine, aniline, benzylamine, phenethylamine, thiophenol, 4-fluorothiophenol, 2-fluorothiophenol, 2,4-difluorobenzenethiol, pentafluorothiophenol, 2,3,5,6-tetrafluorothiophenol, 2-phenylethanethiol, ethanethiol, ethane-1,2-dithiol, 1-propanethiol, isopropylthiol, 1-butanethiol, 1,3-diethyl thiol, 1,3-propanedithiol, and 4-aminothiophenol, or any mixture thereof.

### EMBODIMENT 3

The method according to any of embodiments 1-2, wherein a perovskite film of the PVSC is an organic-inorganic hybrid material or an inorganic material, and has a form of ABX₃, where A is CH₃NH₃⁺, HC(NH₂)₂⁺, Cs⁺, or any combination thereof; B is Pb, Sn, Bi, or any combination thereof; and X is I, Cl, Br, SCN, or any combination thereof.

### EMBODIMENT 4

The method according to any of embodiments 1-3, wherein the exposing the perovskite optoelectronic devices includes exposing the devices in a ligand vapor, a dosage of the ligand is in a range from 1 microliter to 200 microliters, and a treatment duration is in a range from 1 minute to 180 minutes.

### EMBODIMENT 5

The method according to any of embodiments 1-4, wherein the ligand modifies regions of a perovskite film that are not protected by a contact film, and the ligand modified regions of the perovskite film exhibit X-ray diffraction (XRD) peaks at an angle (2 theta) less than 12 degrees.

### EMBODIMENT 6

A perovskite optoelectronic device is fabricated by the method according to any of embodiments 1-5.

### EMBODIMENT 7

A method of manufacturing a ligand treated perovskite optoelectronic device, comprising:
preparing the perovskite optoelectronic device; and
performing a ligand treatment on a lateral region of the perovskite optoelectronic device such that a perovskite film in the lateral region of the device has a ligand modified perovskite film.

### EMBODIMENT 8

The method according to embodiment 7, wherein the performing a ligand treatment includes at least one of spin-coating the perovskite optoelectronic device with a ligand solution, dipping the perovskite optoelectronic device in the ligand solution, and exposing the perovskite optoelectronic device in a ligand vapor.

### EMBODIMENT 9

The method according to any of embodiments 7-8, wherein the ligand modified perovskite film is a low-dimensional material lower than the three-dimensional characteristic of unmodified perovskite film in a central region of the perovskite optoelectronic device.

### EMBODIMENT 10

The method according to any of embodiments 8-9, wherein the exposing the perovskite optoelectronic device in a ligand vapor comprises:
generating a ligand vapor atmosphere in a closed container; and
placing the perovskite optoelectronic device in the ligand vapor atmosphere.

### EMBODIMENT 11

The method according to any of embodiments 7-10, wherein the performing a ligand treatment is done at a room temperature.

### EMBODIMENT 12

The method according to any of embodiments 7-11, wherein a ligand for performing the ligand treatment is at least one of methylamine, dimethylamine, trimethylamine ethylamine, diethylamine, triethylamine, ethylenediamine, diethylentriamine, propylamine, 1,3-diaminopropane, dipropylamine, tri-n-propylamine, isopropylamine, diisopropylamine, 1,2-dimethylpropylamine, 1,2-diaminopropane, diallylamine, cyclopropylamine, butylamine, dibutylamine, isobutylamine, sec-butylamine, 1,4-diaminobutane, tert-butylamine, di is obutylamine, pentylamine, hexylamine, 2-ethylhexylamine, hexamethylenediamine, heptylamine, octylamine, tri-n-octylamine, 1,10-diaminodecane, N,N′-dimethylpropylenediamine, trimethylenediamine, N,N′-dihexyltrimethylenediamine, decamethylenediamine, di(trimethylene)triamine, di(heptamethylene)triamine, triethylenetetraamine, tripropylenetraamine, tetraethylenepentaamine, pentaethylenehexaamine, imidazoline, methylimidazoline, bis(aminoethyl)imidazoline, pyrimidine, aminopropylpiperazine, bis(aminoethyl)piperazine, N-mono(hydroxyethyl) ethyl enediamine, N,N′-bis(hydroxyethyl)ethylenediamine, N-mono(hydroxypropyl)diethylenetriamine and N,N′-bis(hydroxypropyl)tetraethylenepentaamine, aniline, benzylamine, phenethylamine, thiophenol, 4-fluorothiophenol, 2-fluorothiophenol, 2,4-difluorobenzenethiol, pentafluorothiophenol, 2,3,5,6-tetrafluorothiophenol, 2-phenylethanethiol, ethanethiol, ethane-1,2-dithiol, 1-propanethiol, isopropylthiol, 1-butanethiol, 1,3-diethyl thiol, 1,3-propanedithiol, and 4-aminothiophenol, or any mixture thereof.

### EMBODIMENT 13

The method according to any of embodiments 7-12, wherein the ligand solution is used in a range of 1 microliter to 200 microliters.

### EMBODIMENT 14

The method according to any of embodiments 7-13, wherein the perovskite film is at least one of an organic-inorganic hybrid material and an inorganic material.

### EMBODIMENT 15

A ligand treated perovskite optoelectronic device, comprising:
a perovskite film; and
a contact film disposed on the perovskite film and configured to cover a central region of the perovskite optoelectronic device and to expose a lateral region of the perovskite optoelectronic device, wherein the perovskite film located in the lateral region of the perovskite optoelectronic device has a ligand modified perovskite film.

### EMBODIMENT 16

The ligand treated perovskite optoelectronic device according to embodiment 15, wherein the ligand modified perovskite film in the lateral region has a dimension different from the perovskite film in the central region.

### EMBODIMENT 17

The ligand treated perovskite optoelectronic device according to any of embodiments 15-16, wherein the ligand modified perovskite film in the lateral region has an X-ray diffraction peak at an angle less than 12 degrees.

### EMBODIMENT 18

The ligand treated perovskite optoelectronic device according to any of embodiments 15-17, wherein the perovskite film is an organic-inorganic hybrid material or an inorganic material, and has a form of ABX₃, where A is CH₃NH₃⁺, HC(NH₂)₂⁺, Cs⁺, or any combination thereof; B is Pb, Sn, Bi, or any combination thereof; and X is I, Cl, Br, SCN, or any combination thereof.

### EMBODIMENT 19

The ligand treated perovskite optoelectronic device according to any of embodiments 15, wherein the perovskite film sandwiched between an electron transport layer (ETL) and a hole transport layer (HTL).

### EMBODIMENT 20

The ligand treated perovskite optoelectronic device according to embodiment 19, further comprising an electrode disposed on the top of the HTL or ETL.

### EMBODIMENT 21

The perovskite optoelectronic device fabricated by the method can be used as perovskite solar cells, perovskite light-emitting diodes, and photodetectors according to any of embodiments 1-20.

A greater understanding of the present invention and its many advantages may be had from the following examples, given by way of illustration. Following are examples that illustrate procedures for practicing the invention. These examples should not be construed as limiting. All percentages are by weight and all solvent mixture proportions are by volume unless otherwise noted. Numerous changes and modifications can be made with respect to the invention.

### EXAMPLE 1

The perovskite solar cells (PVSCs) are fabricated with the configuration of ITO/NiOₓ/CH₃NH₃PbI₃/PCBM:C₆₀/Zracac/Ag., where room-temperature solution-processed NiOₓ nanostructure, PCBM:C₆₀ mixture, and zirconium acetylacetonate (Zracac) as hole transport layer (HTL), electron transport layer (ETL), and interface layer, respectively. Firstly, ITO-coated glass substrates were cleaned and then ultraviolet-ozone treated for 20 min. Then, the NiOₓ nanoparticles aqueous ink (20 mg/mL in deionized water) was spin-coated on pre-cleaned ITO glass to form nanostructured NiOₓ films as described in our previous reports. See, H. Zhang, J. Cheng, F. Lin, H. He, J. Mao, K. S. Wong, A. K. Y. Jen and W. C. H. Choy, ACS Nano 2016, 10, 1503-1511 (“Zhang”), which is incorporated herein by reference. The resultant NiOₓ films will be used to fabricate devices without annealing process or other treatments. The CH₃NH₃PbI₃ solution were prepared by reacting the 190 mg CH₃NH₃I, 500 mg PbI₂, and 30 mg PbCl₂ in 1 ml anhydrous N,N-dimethylformamide at room temperature for 20 min. To deposit perovskite film, the CH₃NH₃PbI₃ solution was first dropped onto a NiOₓ/ITO substrate. The substrate was then spun at 5000 rpm and after six seconds anhydrous chlorobenzene (180 μl) was quickly dropped onto the center of the substrate, and dried on a hot plate at 100° C. for 10 min. Subsequently, the PCBM:C₆₀ mixture (8+12 mg/mL in dichlorobenzene) and zirconium acetylacetonate solution (2 mg/mL in isopropyl alcohol) were then sequentially deposited by spin coating at 1,000 rpm for 60 s and 4,000 rpm for 30 s, respectively. Finally, the device was completed with the evaporation of Ag electrodes (120 nm) in a high vacuum through a shadow mask. The active area of this electrode was fixed at 6 mm². All devices were fabricated in glove box.

### EXAMPLE 2

To demonstrate the feasibility of the new ligand-induced modification for improving the performance, reproducibility, and stability of PVSCs simultaneously, diethylentriamine (IDEA) is taken as the ligand example to treat CH₃NH₃PbI₃ PVSCs, typically by exposing the CH₃NH₃PbI₃ PVSCs in the IDEA ligand vapor, with a dosage of the ligand in a range from 1 microliter to 200 microliters, and a treatment duration in a range from 1 minute to 180 minutes. As shown in FIG. 1b, the material properties (i.e. CH₃NH₃PbI₃) of region I changes after the IDEA treatment, which can be clearly observed from the color change and XRD patterns (FIG. 1c). The new XRD peaks below 10 degree confirmed the formation of low-dimensional perovskite in region I. As shown in FIG. 2a, the control device without IDEA treatment showed typical performance with a short circuit current density (J_{sc}) of 22.12 mA cm⁻², a V_{oc} of 1.06V, a fill factor (FF) of 79.6%, and a PCE of 18.67%. In striking contrast, the device with IDEA treatment showed a significantly improved performance with a J_{sc} of 23.47 mA cm⁻², a V_{oc} of 1.08V, a FF of 79.4%, and a PCE of 20.13%. In order to investigate the reproducibility of the PVSCs, 37 separate devices were fabricated and tested. The histograms of the device efficiencies are presented in FIG. 2b. The IDEA treatment significantly improves the device reproducibility with a standard deviation of only 1.94% in PCE (4.46% before treatment). Approximate 80% of the treated cells show PCE over 18%.

### EXAMPLE 3

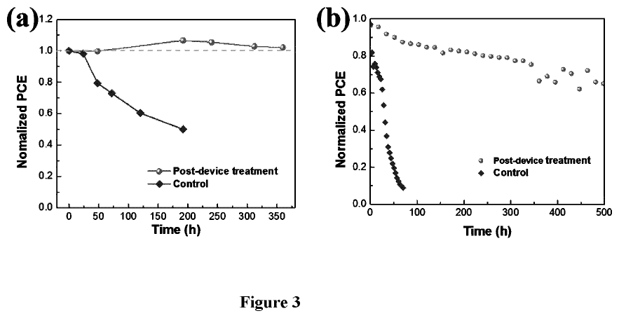

Without the protection of a contact film, the perovskites in the lateral region can be reacted with moisture easily, which accelerates the degradation of the whole devices by forming iodine-containing compounds. See, Y. Han, S. Meyer, Y. Dkhissi, K. Weber, J. M. Pringle, U. Bach, L. Spiccia, Y.-B. Cheng, Journal of Materials Chemistry A 2015, 3, 8139-8147 (“Han”), which is incorporated herein by reference. Low dimensional perovskites show higher stability than conventional three-dimensional perovskites. See, I. C. Smith, E. T. Hoke, D. S.-Ibarra, M. D. McGehee, H. I. Karunadasa, Angew. Chem. 2014, 126, 11414 (“Smith”); D. H. Cao, C. C. Stoumpos, O. K. Farha, J. T. Hupp, M. G. Kanatzidis, J. Am. Chem. Soc. 2015, 137, 7843 (“Cao”); G. Grancini, C. Roldán-Carmona, I. Zimmermann, E. Mosconi, X. Lee, D. Martineau, S. Narbey, F. Oswald, F. De Angelis, M. Graetzel, M. K. Nazeeruddin, Nature Commun. 2017, 8, 15684 (“Grancini”); and H. Tsai, W. Nie, J.-C. Blancon, C. C. Stoumpos, R. Asadpour, B. Harutyunyan, A. J. Neukirch, R. Verduzco, J. J. Crochet, S. Tretiak, L. Pedesseau, J. Even, M. A. Alam, G. Gupta, J. Lou, P. M. Ajayan, M. J. Bedzyk, M. G. Kanatzidis, A. D. Mohite, Nature 2016, 536, 312 (“Tsai”), each of which is incorporated herein by reference in their entirety. The reduction of perovskite dimensionality in the lateral region is a good way to improve the stability of PVSCs. To verify this, the stability of PVSCs was monitored by putting the unencapsulated devices in an ambient atmosphere at room temperature and relative humidity of 50-85%, and the device performances are summarized in FIG. 3a. It is clearly that the control devices show a very fast degradation after exposure to ambient atmosphere. Interestingly, the ligand-induced modified PVSCs retained almost 100% of the initial PCE after storage in ambient conditions for two weeks. FIG. 3b shows the maximum power point (MPP) tracking of the devices. The results show that the PCE of unsealed ligand-modified PVSCs maintained 60% of the initial PCE under 1 sun continuous illumination in ambient environment for 500 h. In contrast, the control device totally degraded within the first 100 hours. These results conclusively confirmed that the ligand-induced post-device treatment could effectively improve the moisture stability of PVSCs.

It should be understood that the examples and embodiments described herein are for illustrative purposes only and that various modifications or changes in light thereof will be suggested to persons skilled in the art and are to be included within the spirit and purview of this application and the scope of the appended claims. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

All patents, patent applications, provisional applications, and publications referred to or cited herein (including those in the “References” section) are incorporated by reference in their entirety, including all figures and tables, to the extent they are not inconsistent with the explicit teachings of this specification.

1. A method of ligand-induced treatment on a perovskite optoelectronic device, the method comprising:
generating a ligand atmosphere;
exposing the perovskite optoelectronic device in the ligand atmosphere; and
removing the perovskite optoelectronic device from the ligand atmosphere.

2. The method according to claim 1, wherein a ligand for generating the ligand atmosphere is methylamine, dimethylamine, trimethylamine, ethylamine, diethylamine, triethylamine, ethylenediamine, diethylentriamine, propyl amine, 1,3-diaminopropane, dipropylamine, tri-n-propylamine, isopropylamine, diisopropylamine, 1,2-dimethylpropylamine, 1,2-diaminopropane, diallylamine, cyclopropylamine, butylamine, dibutylamine, isobutylamine, sec-butylamine, 1,4-diaminobutane, tert-butylamine, diisobutylamine, pentylamine, hexylamine, 2-ethylhexylamine, hexamethylenediamine, heptylamine, octylamine, tri-n-octylamine, 1,10-diaminodecane, N,N′-dimethylpropylenediamine, trimethylenediamine, N,N′-dihexyltrimethylenediamine, decamethylenediamine, di(trimethylene)triamine, di(heptamethylene)triamine, triethylenetetraamine, tripropylenetraamine, tetraethylenepentaamine, pentaethylenehexaamine, imidazoline, methylimidazoline, bis(aminoethyl)imidazoline, pyrimidine, aminopropylpiperazine, bis(aminoethyl)piperazine, N-mono(hydroxyethyl)ethylenediamine, N,N′-bis(hydroxyethyl)ethylenediamine, N-mono(hydroxypropyl)diethylenetriamine, N,N′-bis(hydroxypropyl)tetraethylenepentaamine, aniline, benzylamine, phenethylamine, thiophenol, 4-fluorothiophenol, 2-fluorothiophenol, 2,4-difluorobenzenethiol, pentafluorothiophenol, 2,3,5,6-tetrafluorothiophenol, 2-phenylethanethiol, ethanethiol, ethane-1,2-dithiol, 1-propanethiol, isopropylthiol, 1-butanethiol, 1,3-diethyl thiol, 1,3-propanedithiol, and 4-aminothiophenol, or any mixture thereof.

3. The method according to claim 1, wherein a perovskite film of the perovskite optoelectronic device is an organic-inorganic hybrid material or an inorganic material, and has a form of ABX₃, where A is CH₃NH₃⁺, HC(NH₂)₂⁺, Cs⁺, or any combination thereof; B is Pb, Sn, Bi, or any combination thereof; and X is I, Cl, Br, SCN, or any combination thereof.

4. The method according to claim 1, wherein the exposing the perovskite optoelectronic device includes exposing the perovskite optoelectronic device in a ligand vapor, a dosage of the ligand is in a range from 1 microliter to 200 microliters, and a treatment duration is in a range from 1 minute to 180 minutes.

5. The method according to claim 1, wherein a ligand for generating the ligand atmosphere modifies a region of a perovskite film that is not protected by a contact film, and the ligand modified region of the perovskite film exhibits X-ray diffraction (XRD) peaks at an angle (2 theta) less than 12 degrees.

6. The method according to claim 5, wherein the contact film is carrier transport layer, an electrode, a polymer film, inorganic film, or any mixture thereof.

7. A perovskite optoelectronic device fabricated by the method according to claim 1.

8. A method of manufacturing a ligand modified perovskite optoelectronic device, comprising:
preparing the perovskite optoelectronic device; and
performing a ligand treatment on a lateral region of the perovskite optoelectronic device such that a perovskite film in the lateral region of the perovskite optoelectronic device has a ligand modified perovskite film.

9. The method according to claim 8, wherein the performing a ligand treatment includes at least one of spin-coating the perovskite optoelectronic device with a ligand solution, dipping the perovskite optoelectronic device in the ligand solution, and exposing the perovskite optoelectronic device in a ligand vapor.

10. The method according to claim 9, wherein the ligand modified perovskite film is a low-dimensional material lower than the three-dimensional characteristic of unmodified perovskite film in a central region of the perovskite optoelectronic device.

11. The method according to claim 10, wherein the exposing the perovskite optoelectronic device in a ligand vapor comprises:
generating a ligand vapor atmosphere in a closed container; and
placing the perovskite optoelectronic device in the ligand vapor atmosphere.

12. The method according to claim 10, wherein the performing a ligand treatment is done at a room temperature.

13. The method according to claim 10, wherein a ligand for performing the ligand treatment is at least one of methylamine, dimethylamine, trimethylamine, ethylamine, diethylamine, triethylamine, ethylenediamine, diethylentriamine, propylamine, 1,3-diaminopropane, dipropylamine, tri-n-propylamine, isopropylamine, diisopropylamine, 1,2-dimethylpropylamine, 1,2-diaminopropane, diallylamine, cyclopropylamine, butylamine, dibutylamine, isobutylamine, sec-butylamine, 1,4-diaminobutane, tent-butylamine, diisobutylamine, pentylamine, hexylamine, 2-ethylhexylamine, hexamethylenediamine, heptylamine, octylamine, tri-n-octylamine, 1,10-diaminodecane, N,N′-dimethylpropylenediamine, trimethylenediamine, N,N′-dihexyltrimethylenediamine, decamethylenediamine, di(trimethylene)triamine, di(heptamethylene)triamine, triethylenetetraamine, tripropylenetraamine, tetraethylenepentaamine, pentaethylenehexaamine, imidazoline, methylimidazoline, bis(aminoethyl)imidazoline, pyrimidine, aminopropylpiperazine, bis(aminoethyl)piperazine, N-mono(hydroxyethyl)ethylenediamine, N,N′-bis(hydroxyethyl)ethylenediamine, N-mono(hydroxypropyl)diethylenetriamine, N,N′-bis(hy droxypropyl)tetraethylenepentaamine, aniline, benzylamine, phenethylamine, thiophenol, 4-fluorothiophenol, 2-fluorothiophenol, 2,4-difluorobenzenethiol, pentafluorothiophenol, 2,3,5,6-tetrafluorothiophenol, 2-phenylethanethiol, ethanethiol, ethane-1,2-dithiol, 1-propanethiol, isopropylthiol, 1-butanethiol, 1,3-diethyl thiol, 1,3-propanedithiol, and 4-aminothiophenol, or any mixture thereof.

14. The method according to claim 10, wherein the ligand solution is used in a range of 1 microliter to 200 microliters for spin coating the perovskite optoelectronic device.

15. The method according to claim 10, wherein the perovskite film is at least one of an organic-inorganic hybrid material and an inorganic material.

16. A ligand treated perovskite optoelectronic device, comprising:
a perovskite film; and
a contact film disposed on the perovskite film and configured to cover a central region of the perovskite optoelectronic device and to expose a lateral region of the perovskite optoelectronic device,
wherein the perovskite film located in the lateral region of the perovskite optoelectronic device has a ligand modified perovskite film.

17. The ligand treated perovskite optoelectronic device according to claim 16, wherein the ligand modified perovskite film in the lateral region has a dimension different from the perovskite film in the central region.

18. The ligand treated perovskite optoelectronic device according to claim 16, wherein the ligand modified perovskite film in the lateral region has an X-ray diffraction peak at an angle less than 12 degrees.

19. The ligand treated perovskite optoelectronic device according to claim 16, wherein the perovskite film is an organic-inorganic hybrid or an inorganic material, and has a form of ABX₃, where A is CH₃NH₃⁺, HC(NH₂)₂⁺, Cs⁺, or any combination thereof; B is Pb, Sn, Bi, or any combination thereof; and X is I, Cl, Br, SCN, or any combination thereof.

20. The ligand treated perovskite optoelectronic device according to claim 16, wherein the perovskite film is sandwiched between an electron transport layer (ETL) and a hole transport layer (HTL).
